(19) United States
(12) Patent Application Publication
(10) Pub. No.: US 2016/0087406 A1
(43) Pub. Date: Mar. 24, 2016

(54) White light illuminant comprising quantum dot lasers and phosphors

(71) Applicant: Sandia Corporation, Albuquerque, NM (US)

(72) Inventors: Jonathan Wierer, JR., Coopersburg, PA (US); Jeffrey Y. Tsao, Albuquerque, NM (US); Arthur J. Fischer, Sandia Park, NM (US)

(21) Appl. No.: 14/955,355

(22) Filed: Dec. 1, 2015

Related U.S. Application Data
(63) Continuation-in-part of application No. 13/433,518, filed on Mar. 29, 2012.
Application No. 13/433,518 is a continuation-in-part of application No. 14/624,074, filed on Feb. 17, 2015.
(60) Provisional application No. 61/955,909, filed on Mar. 20, 2014.

(51) Int. Cl. H01S 5/323

(52) U.S. Cl. CPC H01S 5/32341

(57) ABSTRACT

A laser-based white light illuminant comprises a III-nitride quantum dot laser diode and phosphors that convert the emitted laser light into white light. The laser light is emitted from an active region comprised of small quantum dots having a narrow size distribution, thereby providing narrower linewidths, decreased operating current density and increased peak efficiency. The white light illuminant has a number of advantages of LED-based solid state lighting, including higher power conversion efficiency, higher achievable luminous efficacy, and new and improved functionality.

### CROSS-REFERENCE TO RELATED APPLICATIONS

This application is a continuation-in-part of application Ser. No. 13/433,518, filed Mar. 29, 2012, and a continuation-in-part of application Ser. No. 14/624,074, filed Feb. 17, 2015, which claims the benefit of U.S. Provisional Application No. 61/955,909, filed Mar. 20, 2014, each of which is incorporated herein by reference.

### STATEMENT OF GOVERNMENT INTEREST

This invention was made with Government support under contract no. DE-AC04-94AL85000 awarded by the U.S. Department of Energy to Sandia Corporation. The Government has certain rights in the invention.

### FIELD OF THE INVENTION

The present invention relates to solid-state lighting and, in particular, to a white light illuminant comprising quantum dot lasers and phosphors.

### BACKGROUND OF THE INVENTION

III-nitride laser diodes (LDs) are an interesting light source for solid-state lighting (SSL) because of the advantages they may provide over light-emitting diodes (LEDs). Foremost, blue III-nitride LDs have higher power conversion efficiency (or wall-plug efficiency) at high current densities compared to blue III-nitride LEDs. This is because Auger recombination that causes the drop in efficiency (efficiency droop) at high currents in III-nitride LEDs (See Y. C. Shen et al., Appl. Phys. Lett. 91, 141101 (2007); N. F. Gardner et al., Appl. Phys. Lett. 91, 243506 (2007); E. Kioupakis et al., Appl. Phys. Lett. 98, 161107 (2011); and A. Laubsch et al., Phys. Status Solidi C 6, Suppl. 2, S913 (2009); J. Iveland et al., Phys. Rev. Lett. 110, 5 (2013)) cannot grow (is clamped) in LDs after threshold. See J. J. Wierer, Jr. et al., Laser Photon. Rev. 7, 963 (2013); J. J. Wierer, Jr. et al., Phys. Status Solidi C 11, 674 (2014); and A. Neumann et al., Opt. Express 19, A982 (2011). Therefore, substituting LDs for LEDs as a SSL source is a method to circumvent efficiency droop. This could enable high flux emitters with high efficiencies at higher current densities.

Advantages of III-nitride LDs are not limited to efficiency. Other LD advantages include the ability to create white light using phosphor conversion, exploitation of the LD's directional beam enabling new functionality in luminaires and applications, narrow linewidths that provide higher achievable luminous efficacies, and fast switching for control in space and time for high light usage efficiencies. All are compelling reasons to pursue LDs for SSL. See J. J. Wierer, Jr. et al., Phys. Status Solidi C 11, 674 (2014); A. Neumann et al., Opt. Express 19, A982 (2011); Y. Narukawa et al., Oyo Butsuri 74, 1423 (2005); S. Saito et al., in: IEEE Int. Semiconductor Laser Conf., Sorrento, IT, 2008 (IEEE, Washington, D.C., 2008), pp. 185-186; K. A. Denault et al., AIP Adv. 3, 072107 (2013); J. Y. Tsao et al., Adv. Opt. Mater. 2, 809 (2014); and J. M. Phillips et al., Laser Photon. Rev. 1, 307 (2007).

However, although the advantages of LDs are compelling, there are some disadvantages that need to be addressed before LDs can become truly competitive with LEDs for SSL. These disadvantages include improvements in efficiency and reduction in cost.

### SUMMARY OF THE INVENTION

The present invention is directed to a laser-based white light illuminant, comprising a III-nitride semiconductor laser diode, wherein short visible wavelength laser light is emitted from an active region comprised of quantum dots (QDs); and one or more phosphors that convert at least a portion of the emitted laser light to longer wavelength light, wherein the spectral power density of the unconverted laser light and phosphor-converted light produces white light. For example, the short visible wavelength of the laser light can be between 365 nm and 465 nm. For example, the semiconductor laser diode can be a distributed feedback laser, photonic crystal QD laser, edge-emitting QD laser, or a vertical-cavity surface-emitting QD laser. The QDs can emit laser light with an energy distribution less than 200 meV. The QDs can comprise InGaN or GaN QDs that are formed by photoelectrochemical etching. For example, the phosphors can emit at wavelengths between 465 nm and 650 nm. The directional emission of a LD can be more easily captured and focused onto the phosphors to create higher luminance white sources. The white light can have a correlated color temperature between 2000 and 8000K, a color rendering index of greater than 75, and a luminous efficacy of greater than 325 Im/W. In another embodiment, the phosphors can be translated in space, thereby changing the chromaticity of the white light. In particular, the phosphors can produce varying correlated color temperature when translated relative to the short wavelength laser light. The white light illuminant can further comprise a movable lens, providing tunable focusing and directability into an illumination space, and a speckle-reducing element.

Such high-brightness LD sources enable novel and more compact luminaires. Further, the smaller area and higher current density operation of LDs provides them with a potential cost advantage over LEDs.

### BRIEF DESCRIPTION OF THE DRAWINGS

The detailed description will refer to the following drawings, wherein like elements are referred to by like numbers.

FIG. 1(a) is a graph of power conversion efficiency versus current density of state-of-the-art (SOTA) and future blue LEDs and LDs. FIG. 1(b) is a graph of recombination rate versus current density for SOTA LEDs and LDs. The dashed lines are for LD rates after threshold that can no longer grow.

FIG. 2(a) is a schematic illustration of a violet laser diode emitting onto three different phosphors via a lens to focus the light to form a full white spectrum PC-LD. FIG. 2(b) is a graph of relative spectral power density versus wavelength of the three phosphors, the violet LD, the resulting full spectrum white light, and a tungsten-filament source spectrum as a reference.

FIG. 3 is a graph of power conversion efficiency versus wavelength for state-of-the-art InGaN and AlInGaP LDs. The two data points at the deep green and red use quantum-dot (QD) active regions.

FIG. 4 is a graph of emitter area versus phosphor area for the PC-LED and PC-LD. Insets are cross-sectional schematics for the PC-LED (upper left) and PC-LD (lower right). The reflector cup angle is θ and the distance from the emitter to phosphor is d.

FIG. 5 is a schematic illustration of a smart, ultra-efficient white LD micro-luminaire.

FIG. 6(a) is a schematic illustration of the absorption of the laser light in a large QD. FIG. 6(b) is a schematic illustration of self-termination of a quantum-size-controlled photoelectrochemical (QSC-PEC) etch in a smaller sized and higher absorption energy QD. FIG. 6(c) is a side-view image of a single InGaN QD. FIG. 6(d) shows PL spectra of Stranski-Krastanov (SK) and QSC-PEC QD ensembles.

### DETAILED DESCRIPTION OF THE INVENTION

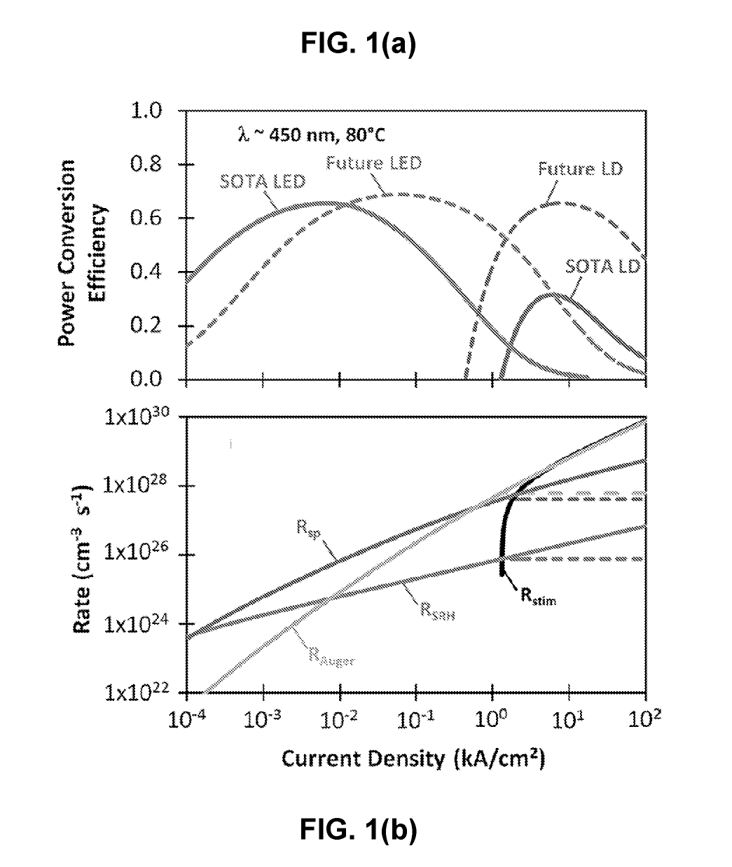

The most compelling reason to consider LDs for SSL is because state-of-the-art blue LDs have higher efficiencies than state-of-the-art blue LEDs at high current densities. See J. J. Wierer, Jr. et al., Laser Photon. Rev. 7, 963 (2013); and U.S. application Ser. No. 13/433,518. FIG. 1(a) shows this advantage where power conversion efficiency (PCE) versus current density is plotted for a state-of-the-art (SOTA) blue thin-film LED and blue edge-emitting LD (solid lines). See Philips-Lumileds, LUXEON Rebel Color Porfolio Datasheet DS68 20111201 (2011); and C. Vierheilig et al., Proc. SPIE 8277, San Francisco, Calif., USA, 2012 (SPIE, Bellingham, 2012), pp. 82770K1-82770K7. The SOTA blue LED has high peak PCE, but it occurs at very low current densities (˜5 A/cm²) and drops as the current density increases. The SOTA LD, on the other hand, has a peak PCE at ˜5 kA/cm², which is much higher than the LED's PCE at those current densities. The PCE of the LD does eventually drop at higher current densities, but this decrease is caused by resistive losses, while the LEDs drop in PCE is caused by both Auger recombination (efficiency droop) and resistive losses.

The reason why LDs are not subject to efficiency droop can be understood by considering the recombination processes within the quantum wells (QWs) of the LD. The total rate of recombination of carriers (Rₜₒₜₐₗ) can be written as:

Rₜₒₜₐₗ=R_{SRH}+Rₛₚ+R_{Auger}+Rₛₜᵢₘ, (1)

where R_{SRH} is the non-radiative Shockley-Read-Hall recombination rate, Rₛₚ is the spontaneous recombination rate, R_{Auger} is the non-radiative Auger recombination rate, and Rₛₜᵢₘ is the stimulated recombination rate. The recombination rates versus current density for the state-of-the-art blue LED and LD are plotted in FIG. 1(b). At low current densities the recombination of carriers is caused by Shockley-Read-Hall, spontaneous, and Auger recombination for both the LED and LD. This analysis assumes that the QW active regions are the same for the LED and LD, resulting in the same rates. See J. J. Wierer, Jr. et al., Laser Photon. Rev. 7, 963 (2013). The LED produces light at low current densities because the LED is designed for high light extraction. The LD, on the other hand, does not produce light at low current densities, because it is designed to contain and create a large photon density that leads to stimulated emission. Auger recombination is low at low current densities, but grows rapidly as the current increases and eventually dominates the total recombination rate. This causes a lowering in the radiative efficiency (η_{rad}) that can be written as:

$${η}_{rad} = \frac{{R}_{sp}}{{R}_{SRH} + {R}_{sp} + {R}_{Augur}} \qquad ( 2 )$$

The higher the current density the greater the Auger recombination rate, leading to a decrease in η_{rad}. Auger recombination not only affects the efficiency of light produced within the LED, but also affects the threshold current of the LD. See J. J. Wierer, Jr. et al., Laser Photon. Rev. 7, 963 (2013).

The large photon density that builds within the LD cavity with increased current density provides a method to circumvent the efficiency droop. When the optical gain in the LD overcomes the losses, laser threshold is obtained (˜1.2 kA/cm²) and the LD finally emits an appreciable amount of light. The non-stimulated recombination processes (R_{SRH}, Rₛₚ and R_{Auger}) can no longer grow (are clamped). This is shown in FIG. 1(b) where those recombination rates no longer increase (dashed lines). After threshold, the LD's steady-state optical gain cannot increase because the internal field would also grow without bound. Clamping of the optical gain implies clamping of the carrier density. See L. A. Coldren et al., Diode Lasers and Photonic Integrated Circuits (Wiley, Hoboken, N.J., 2012). This clamped carrier density prevents the further growth of R_{SRH}, Rₛₚ and R_{Auger} after threshold. Because Rₛₜᵢₘ is not similarly clamped, it comes to dominate the recombination and emission process. Therefore, after threshold the III-nitride LD is not subject to increasing Auger recombination losses (and R_{SRH}, Rₛₚ), and thus at these high current densities has a much higher PCE than the LED. See J. J. Wierer, Jr. et al., Laser Photon. Rev. 7, 963 (2013).

The state-of-the-art LD has a peak PCE that is lower than the peak PCE of the state-of-the-art LED. Projections of future improvements, though, suggest the LD efficiency may be able to rival the efficiency of the LED as shown in FIG. 1(a). See J. J. Wierer, Jr. et al., Laser Photon. Rev. 7, 963 (2013). Various methods can be used to improve the efficiency of both blue LEDs and LDs. The result is a peak PCE of the future LD that is close to the peak PCE of the future LED (dashed lines). No definitive way to eliminate Auger recombination was determined by this analysis, partly because Auger recombination is a fundamental physical property of III-nitride semiconductors. Therefore, blue III-nitride LEDs will always have efficiency droop. This will ultimately limit the operating current densities and power per device of the LED while still retaining reasonable efficiency. If operated at peak PCE, the future LD would produce more photons per area than the future LED, resulting in a higher lumens per device, which is key for the LD to compete economically with LED. See J. J. Wierer, Jr. et al., Laser Photon. Rev. 7, 963 (2013). The conclusion is that LDs will always be more efficient than LEDs at high current densities, and should be considered (even at today's efficiencies) in applications where high flux from a single emitter is desired.

Another requirement of LDs for SSL is the ability to create white light. Fortunately, similar phosphor conversion schemes and materials used in white phosphor-converted LEDs (PC-LEDs) can also be used with LDs. In fact, there are many previous reports of white phosphor-converted LDs (PC-LDs). See J. J. Wierer, Jr. et al., Phys. Status Solidi C 11, 674 (2014); Y. Narukawa et al., Oyo Butsuri 74, 1423 (2005); S. Saito et al., IEEE Int. Semiconductor Laser Conf., Sorrento, IT, 2008 (IEEE, Washington, D.C., 2008), pp. 185-186; K. A. Denault et al., AIP Adv. 3, 072107 (2013). A PC-LED and PC-LD using the same phosphor plate produces white light with the same color rendering and color temperature. See J. J. Wierer, Jr. et al., Phys. Status Solidi C 11, 674 (2014). The narrow linewidth of the LD does produce a spectral gap (no light) between the blue LD spectra and the phosphor's longer wavelength spectra. Methods to determine color rendering such as the color rendering index (CRI) and the color quality scale (CQS) suggest white light produced with narrow linewidth spectra is sufficient for good color rendering. See A. Neumann et al., Opt. Express 19, A982 (2011). Contrarily, more stringent methods suggest spectral gaps could pose a problem for color rendering of some objects with narrow band or sharp reflectance spectra. See A. David, Leukos. 10, 59 (2014). Therefore, LD white sources with spectral gaps could possibly be relegated to special applications where spectral gaps are not of importance.

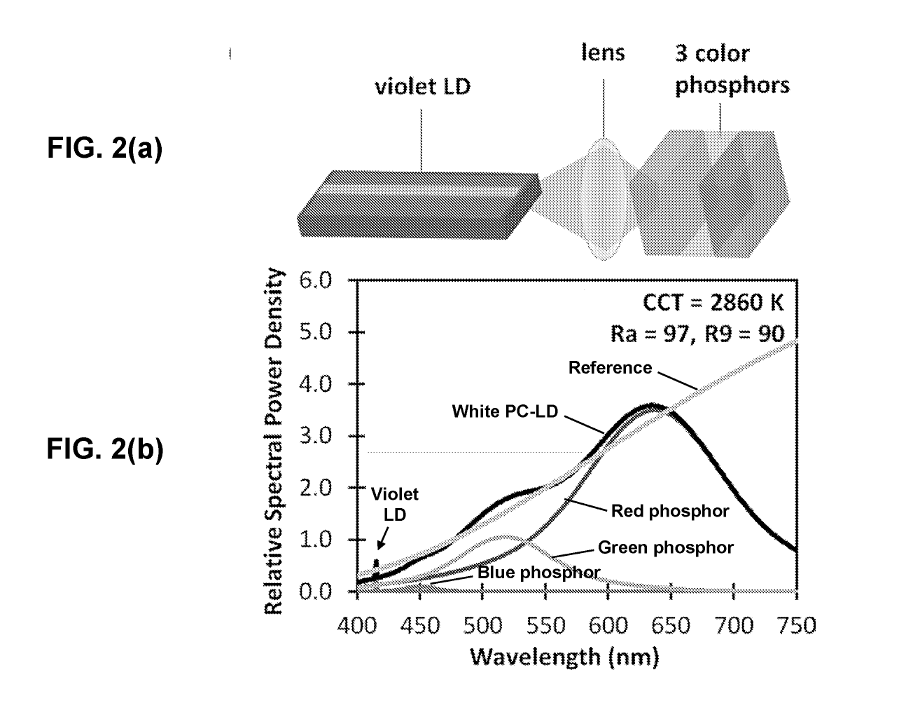

Another method to produce white light is to use multiple phosphors to fill the visible spectrum. This solution avoids the narrow spectra of the LDs and spectral gaps. Such a configuration is shown in FIG. 2(a) where a light from a violet LD is focused onto three different phosphors. Simulation of a violet LD (415 nm and 1 nm spectral width) pumping three color phosphors emitting red (637 nm), green (518 nm) and blue (450 nm) light with spectral widths of 30 nm, 100 nm, and 150 nm, respectively is shown in FIG. 2(b). The color and linewidths of the phosphors are chosen to approximately match those of commercial LED white solutions. See A. David, Leukos. 10, 59 (2014). The color temperature, general color rendering index (Rₐ), and saturated red index (R₉) are 2860 K, 97, and 90, respectively. These values are similar to a violet LED pumping similar phosphors. See A. David, Leukos. 10, 59 (2014). This is not surprising because the spectra of the three phosphors determine the color rendering and color temperature, while the LDs' pump wavelength has little impact. This simple simulation in FIG. 2(b) shows that PC-LDs can also produce full spectrum white light with excellent color rendering.

Although PC-LEDs and PC-LDs can create white spectra with excellent color rendering, they are limited in other areas. Converting blue light to longer wavelengths results in a Stokes efficiency loss, and limits the luminous efficacy of PC-LEDs and PC-LDs. White light produced from color mixed direct emitters (such as red, green, and blue LEDs) do not have this efficiency limitation. In fact, white light produced from the narrow linewidths of LDs with red, yellow, green, and blue wavelengths have luminous efficacies that are higher than white from color mixed LEDs. See J. M. Phillips et al., Laser Photon. Rev. 1, 307 (2007). This white laser source provides good color rendering under human testing. See A. Neumann et al., Opt. Express 19, A982 (2011); and U.S. application Ser. No. 13/433,518. As discussed above, such white light with spectral gaps can have color rendering problems with certain objects, but in applications where efficiency is more valued than color rendering, or if more laser lines are used to fill the spectrum, such a source could be valuable.

Another, and maybe more important, advantage of using color mixed emitters to produce white light is the ability to chromaticity tune. It is now known that human circadian rhythms are affected by light, and blue light suppresses the sleep inducing melatonin release from intrinsically photoreceptive retinal ganglion cells. See R. J. Lucas et al., Trends Neurosci. 37, 1 (2014); and D. M. Berson et al., Science 295, 1070 (2002). Exposure, even at low light levels to blue light prior to sleeping (such as by exposure to LED-backlit computer screens, can disturb sleep cycles which, in turn, can lead to poorer health. See C. Cajochen et al., J. Appl. Physiol. 110, 1432 (2011). Many other studies show that human performance is also affected by light. For example, students perform better in the classroom when the color temperature of the classroom's light is higher. See P. J. C. Sleegers et al., Light Res. Technol. 159 (2012). Therefore, producing chromaticity tunable white sources that can change throughout the day is very important for human health, and should remain a goal for future SSL sources.

Although some white commercial products use color mixed LEDs, they are a smaller segment of SSL compared to phosphor-converted white sources. Adoption of color mixed white is lagging because of a lack of efficient emitters in the green-orange spectral range. This deficiency is called the “green-gap”. It is a result of a decrease in efficiency of InGaN-based emitters at wavelengths longer than blue, and of AlInGaP-based emitters at wavelengths shorter than deep red. See M. R. Krames et al., J. Disp. Technol. 3, 160 (2007).

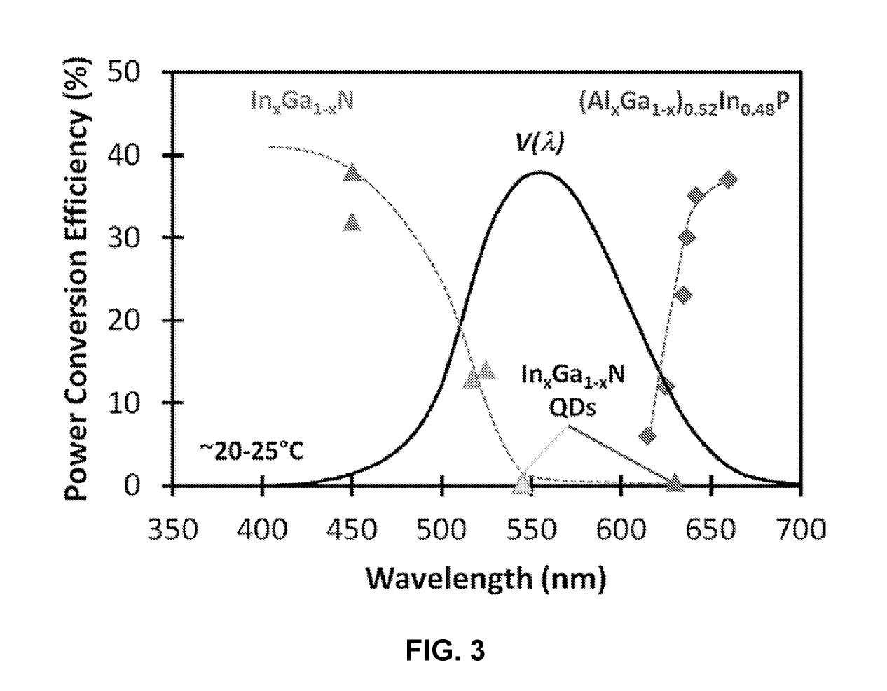

The green-gap is not only a problem for LEDs, but also for LDs. FIG. 3 shows the power conversion efficiency versus wavelength for the best reported InGaN and AlInGaP LDs that shows a lack of efficient emitters at green-gap wavelengths. See U. Strauss et al., Proc. SPIE 8986, San Francisco, Calif., USA, 2014 (SPIE, Bellingham, 2014), pp. 89861L1-89861L10; S. Masui and S. Nagahama, Laser Rev. 41, 899 (2013); Sony Develops World's Highest Optical Output 7.2 W, 635 nm Wavelength Red Semiconductor Laser Array (2008), http://www.sony.net/SonyInfo/News/Press/200808/08-099E/index.html; N. Shimada et al., Proc. SPIE 7198, San Francisco, Calif., USA, 2009 (SPIE, Bellingham, 2009), pp. 719806-1-719806-8; N. Shimada et al., IEEE J. Sel. Top. Quantum Electron. 17, 1723 (2011); K. Shibata et al, IEEE J. Sel. Top. Quantum Electron. 11, 1193 (2005); and D. P. Bour et al., IEEE Photonic. Tech. Lett. 6, 128 (1994). The congruent green-gap problem in LDs and LEDs is of no surprise, because the spontaneous emission rate which limits LEDs is related to optical gain which limits LDs. Since the green-gap problems of LEDs and LDs are related, any improvements made in the LED's spontaneous emission efficiency should translate to the LD's optical gain and efficiency.

Research still continues to improve efficiency at green-gap wavelengths. Large improvements in AlInGaP emitters at green-gap wavelengths are not likely because of detrimental physical limitations. See J. M. Phillips et al., Laser Photon. Rev. 1, 307 (2007). To achieve shorter wavelengths necessitates increasing the Al within the QW. This causes the indirect valley (X-valley) to dominate and electron leakage to increase over smaller barriers; both leading to lower radiative efficiency. InGaN, too, has physical limitations that cause lower efficiencies in the green-gap. These include lattice mismatch strain of InGaN layers grown on GaN leading to non-radiative defects, and polarization-induced fields separating electronic states and decreasing the spontaneous emission rate. See F. Scholz et al., Mater. Sci. Eng. B 50, 238 (1997); and V. Fiorentini et al., Phys. Rev. B 60, 8849 (1999). The latter can be overcome be using less polar substrates, while the former requires a more ingenious approach. See D. F. Feezell et al., J. Disp. Technol. 9, 190 (2013). One promising approach is to use AlGaN interlayers that has shown increases in LED efficiency at green-gap wavelengths. See S. Saito et al., Appl. Phys. Express 6, 111004 (2013); and J. I. Hwang et al., Appl. Phys. Express 7, 071003 (2014). Another approach is to use InGaN quantum dot (QD) active regions that have demonstrated lasing at green-gap wavelengths, as shown in FIG. 3. See P. Bhattacharya et al., Proc. SPIE 8640, San Francisco, Calif., USA, 2013 (SPIE, Bellingham, 2013), pp. 86400J1-86400J6; and T. Frost et al., IEEE J. Quantum. Electron 49, 923 (2013). The lower lattice mismatch strain and higher optical gain provided by the higher density of states in QDs may be a method to improve green-gap LDs (and possibly LEDs).

LDs could also have advantages for luminaires, enabling sizes that cannot be achieved with LEDs because of the LD's directional emission. The beam of light emitted from the LD can be more easily collected and focused, compared to the LED's Lambertian emission.

Table 1 shows a calculation of radiance for a state-of-the-art blue LED and LD. Both sources emit 1 Watt of power. The emitting area of the LED is much larger than the emitting area (aperture) of the LD that assumes 15 mm×1 mm. This small emitting aperture coupled with the smaller collection angle results in a much higher radiance for the LD compared to the LED.

TABLE 1
Radiance of a blue LED and LD.

| parameter | blue LED | blue LD |
|---|---|---|
| power (W) | 1 | 1 |
| emitting area (cm²) | 0.01 | 1.5 × 10⁻⁷ |
| half angle (°) | 45 | 15 |
| radiance (W/str/cm²) | 54 | 3 × 10⁷ |

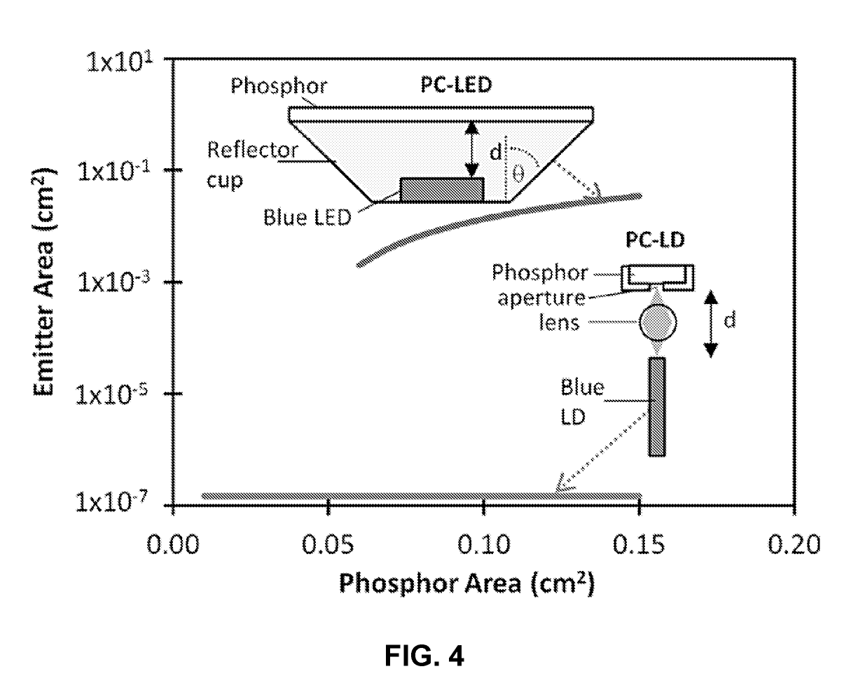

The LD's higher radiance translates into the possibility of using smaller area phosphors. The insets for FIG. 4 show cross-section schematics for a white PC-LED and a PC-LD. In the PC-LED the phosphor plate is the same area as the LED, or larger if used in a remote configuration so that all pump light is incident on the phosphor. See Philips-Lumileds, LUXEONFlash 7DatasheetDS112, (2013); and H. Bechtel et al., Proc. SPIE 7784, San Diego, Calif., USA, 2010, (Bellingham, Wash., 2010), pp. 77840W1-77840WM. Therefore, the area of the phosphor is dependent on the area of the LED as shown in the plot of phosphor area versus device emitter area in FIG. 4. Attempts to create a higher luminance source with the PC-LED by reducing the LED area will be counterproductive. This is because the LED would have to be driven at higher current densities to compensate for the smaller area, and hence operate at lower PCE (FIG. 1). The LD, on the other hand, can have a phosphor area that is much smaller than the LED, because the light can be focused. The phosphor area is not coupled with the LD's aperture area, and remains constant for reasonably sized phosphors.

Results of phosphor-converted luminance calculations are shown in Table 2 using the blue LED and LD radiance from Table 1. The white light from the phosphor is collected with the same half angle for both cases, but because the phosphor area can be smaller for the PC-LD, its luminance is higher. The phosphor areas are somewhat arbitrary, but are reasonable and are used to highlight the possible luminance benefit. Of course, the power density of the light from the blue LD cannot be so high that it damages the phosphor or leads to heating that can reduce phosphor conversion efficiency. The heat dissipation in phosphor plates have been shown to be superior to typically used phosphor loaded organics at high power densities. See F. Tappe, 10th International Symposium on Automotive Lighting—ISAL 2013, Darmstadt, Germany, 2013 (Herbert Utz, Müchen, 2013), pp. 159-167.

TABLE 2
Luminance of a phosphor-converted LED and LD.

| parameter | PC-LED | PC-LLD |
|---|---|---|
| power (lm) | 250* | 250* |
| emitting area (cm²) | 0.09** | 0.01 |
| half angle (°) | 45 | 45 |
| luminance (lm/str/cm²) | 1.5 × 10³ | 1.4 × 10⁴ |

*Assumes 250 lm/W from the phosphor.
**Assumes a square geometry, and a remote phosphor that is d = 1 mm from the LED within a θ = 45° reflector cup.

The PC-LDs smaller phosphor area enables lighting solutions that are not possible with PC-LEDs. For example, lens size is typically determined by the size of the source (phosphor area) in order to avoid internal total reflection of any incident light rays (Weierstrass condition). The smaller phosphor areas in the PC-LD allow for a smaller lens. Using the values in Table 2, the lens area could be a factor of 10 smaller than the PC-LEDs. Therefore, PC-LDs enable micro-luminaires, possibly useful in new lighting applications where the luminaire can be less conspicuous or more efficiently coupled to small optical elements.

As described above, higher current density operation can provide LDs with an economic advantage over LEDs. This is because, for similar efficiencies, the higher the current density the higher the produced photon flux density. So, for a given desired total photon flux, as the operating current density increases the chip size and expense decreases. The difference between the emitters is large: since LDs operating at their peak PCE are driven approximately 10-100 times harder than LEDs operating at their peak PCE, LD chips can be 10-100 times smaller than LED chips. Said differently, LDs can be 10-100 times more expensive per unit chip area, and still be cost competitive with LEDs.

Of course, other considerations could reduce this 10-100 times advantage. These considerations include—LDs might have shorter lifetimes than LEDs, LDs might have lower peak efficiencies than LEDs, and LD chips might require more processing and thus be more expensive per unit area than LED chips. Despite these concerns—LD lifetimes are increasing steadily, by circumventing Auger recombination LDs might someday have peak efficiencies that rival LEDs, and LED chips are becoming more process intensive. In other words, LDs have an inherent 10-100 times cost advantage over LEDs, an advantage that will be difficult for LEDs to overcome.

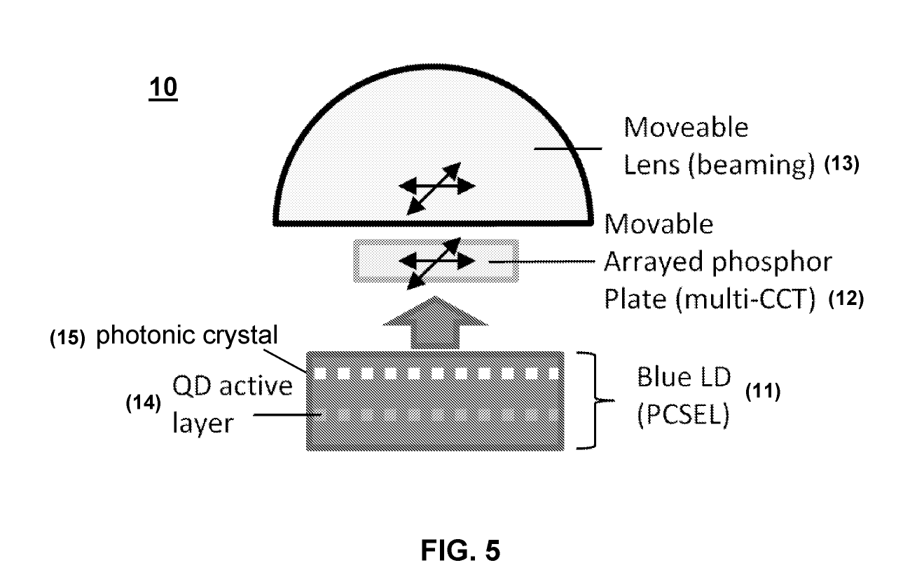

Therefore, LD-based SSL can be both ultra-efficient (at low cost) and ultra-high utility (smart). A schematic illustration of an efficient and smart LD-based white light illuminant 10 comprising a quantum dot laser and phosphors is shown in FIG. 5. A short visible wavelength (violet-blue) LD 11 pumps a red/yellow/green phosphor 12 with the resulting white light that can be focused and steered by a moveable lens 13 into an illumination space. The LD can be made ultra-efficient through the use of InGaN or GaN quantum dot (QD) gain media 14, and the photons are low cost because the LD's peak efficiency occurs at a current density 10-100 times higher than that at which an LED's peak efficiency occurs. The QDs preferably emit at a short visible wavelength (e.g., between 365 and 465 nm) in a narrow bandwidth (e.g., energy distribution less than 200 meV). The LD can be a photonic-crystal 15 surface-emitting laser (PCSEL) 11 with three key features: it is surface emitting and therefore compatible with low-cost planar processing even up to the package/micro-luminaire level, it allows for engineered placement of the QDs in lateral optical field antinodes for maximum gain, and it has a small aperture thus enabling compact and inexpensive micro-optics and packaging. See K. Hirose et al., Nature Photonics 8,406 (2014). Alternatively, the laser diode can be a distributed feedback laser, an edge-emitting laser or a vertical-cavity surface-emitting laser. The LD can pump a laterally translatable variable-composition phosphor plate 12 thus giving the emitted white light tunable chromaticity. The plate 12 can comprise phosphors that emit at wavelengths between about 465 and 650 nm. The phosphors can be comprised of different colors that produce varying correlated color temperature (CCT) when scanned by the short wavelength laser light. The white light can have a CCT between 2000 and 8000 K, a CRI greater than 75, and a luminous efficacy greater than 325 Im/W. The white light can be collected by a vertically and laterally translatable lens 13 which enables tunable focusing and directability into an illumination space. Further, one or more additional light sources, such as light-emitting diodes or laser diodes, can be used to further enhance the color rendering ability of the white light illuminant. Finally, a speckle reduction element, such as a diffractive optical element, a diffuser plate, and/or a piezoelectric element, can be used to reduce speckle of the white light.

Such a micro-luminaire combines ultra-efficiency and ultra-smartness, and indeed these two features feed each other in a virtuous spiral. See J. Y. Tsao et al., Adv. Opt. Materials 2, 809 (2014). Because it is ultra-smart, it enables higher efficiencies for light “usage”—focusing and steering light only when and where it is needed, and tailoring chromaticities to optimize human health and productivity. Because it is ultra-efficient, it enables compact yet thermally viable packages which support microsystem-based mechanisms for translational motion and smartness.

As described earlier, LD-based SSL can overcome the fundamental problem with state-of-the-art InGaN LEDs: their decrease in efficiency at high current densities (efficiency droop). As current density increases, LED efficiency peaks then decreases, as shown in FIG. 1(a), due to Auger recombination outcompeting radiative recombination by spontaneous emission. Because Auger recombination is fundamental, it is not likely to be circumvented by incremental improvements to an LED, so one of two undesirable choices must be made—either the LED is run at peak efficiency but at low current densities (and thus high cost per photon), or it is run at high current densities (and thus low cost per photon) but at much reduced efficiency.

In LDs, in contrast, radiative recombination is dominated by fast stimulated emission. Therefore, above lasing threshold, carrier densities and Auger recombination are clamped and SOTA LDs have higher efficiencies than SOTA LEDs do, as shown in FIG. 1(b). See E. E. Okahisa et al., Rāzā kenkū 41, 230 (2013); J. J. Wierer et al., Lasers and Photonics Review 6, 963 (2013); and J. J. Wierer et al., physics status solidi (c) 11, 674 (2014). The 40% peak efficiency of the SOTA LD, however, is still lower than the peak efficiency of LEDs, as shown in FIG. 1(a). The reason: SOTA LDs use quantum wells (QWs) as their gain media. With such active regions, the 60% “inefficiency” can be broken down roughly into 25% electrical resistive loss, 20% optical absorption loss, and 15% spontaneous emission and Auger recombination losses—with both the first (resistive) and last (spontaneous emission and Auger recombination) losses associated with the high threshold and operating current densities associated with QW gain media. Thus, though calculations suggest that modest improvements such as higher gain from non-c-plane orientations and lower gain broadening can be made to improve performance, radically different gain media are essential to lowered threshold and operating current densities and hence to radically reduced losses.

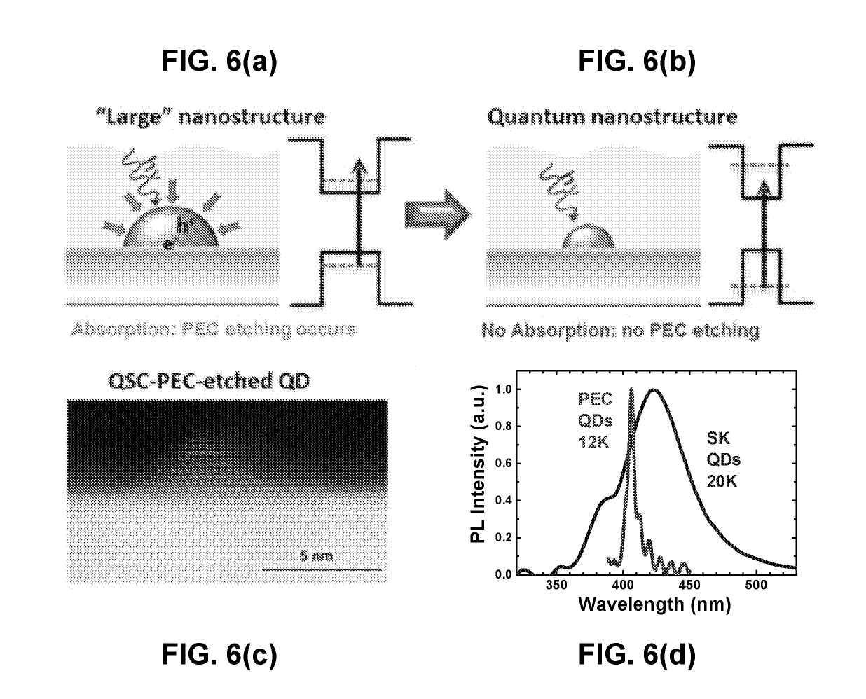

Accordingly, the present invention can use InGaN or GaN QDs as a gain medium. Quantum-size-controlled (QSC) photoelectrochemical (PEC) etching can be used to achieve such QDs. See X. Xiao et al., Nanoletters 14, 5616 (2014); and U.S. application Ser. No. 14/624,074. QSC-PEC etching creates QDs that are more precisely size controlled than those created by additive (spontaneous growth) or other subtractive (simple lithography) methods. As illustrated in FIG. 6(a), an initial QD with a too-large size can be QSC-PEC etched using above-bandgap monochromatic light from a narrowband laser for photoexcitation. Initially, the QD absorbs the laser light, carriers are created, and the QD is PEC etched. Photoexcitation depends on light absorption; light absorption depends on bandgap; and in the quantum-size regime bandgap depends on nanostructure size. In particular, as the size of a nanostructure gets smaller, the bandgap goes up. Thus, properly selected narrowband light will be absorbed by large but not small nanostructures, and, therefore, PEC etching can be self-terminated at a size determined by the wavelength of that narrowband light. Thus, as the QD shrinks, its absorption edge blue shifts due to quantum confinement. When the QDs absorption edge has shifted higher than the energy of the laser, the QD no longer absorbs the laser light, and the PEC etch self-terminates, as shown in FIGS. 6(b) and 6(c). The precise final size of the QD is determined largely by the energy of the laser light.

This quantum-sized controlled method creates QDs with a much narrower size distribution and smaller dot size than do other methods. FIG. 6(d) shows much narrower full width at half maximum (FWHM) photoluminescence (PL) linewidths from ensembles of QSC-PEC InGaN QDs than from ensembles of self-assembled Stranski-Krastanov (SK) InGaN QDs. This method produces small-sized dots (volume less than 60 nm³) which limits the number of electronic states within the dots and in turn limits the carrier density required for laser threshold.

The narrower linewidths and small dot size indicate not only a narrower size distribution, but a spectrally sharpened electronic density of states (eDOS) and, most importantly, the potential for much lower carrier transparency, threshold, and operating carrier (current) densities. Indeed, 10-100 times decrease in operating current density and an increase in peak efficiency to 65% may be achievable. This efficiency increase comes from a 25% to 10% decrease in resistive loss and a 15% to 5% decrease in spontaneous and Auger losses. Even with this 10-100 times decrease in operating current density, LD peak efficiency still occurs at 10-100 times higher current density than that at which LED peak efficiency occurs, so LD photons are still potentially 10-100 times lower in cost than LED photons. Further, there is a near-halving of waste heat for a given output power, so high and often-heat-sink-limited output powers become easier to achieve at low packaging cost. The combination of high efficiency, high output photons/cm² and low packaging cost promises the lowest cost ($/photon) sources of visible photons yet created.

The present invention has been described as a white light illuminant comprising quantum dots and phosphors. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A laser-based white light illuminant, comprising:
a III-nitride semiconductor laser diode, wherein short visible wavelength laser light is emitted from an active region comprised of quantum dots; and
one or more phosphors that convert at least a portion of the emitted laser light to longer wavelength light, wherein the spectral power density of the unconverted laser light and the phosphor-converted light produces white light.

2. The white light illuminant of claim 1, wherein the short visible wavelength of the emitted laser light is between 365 nm and 465 nm.

3. The white light illuminant of claim 1, wherein the semiconductor laser diode comprises a distributed feedback laser, photonic crystal laser, edge-emitting laser, or a vertical-cavity surface-emitting laser.

4. The white light illuminant of claim 1, wherein the quantum dots emit laser light with an energy distribution less than 200 meV.

5. The white light illuminant of claim 1, wherein the quantum dots are comprised of InGaN or GaN.

6. The white light illuminant of claim 1, wherein the quantum dots are formed by photoelectrochemical etching using monochromatic light.

7. The white light illuminant of claim 6, wherein each of the quantum dots has a volume of less than 60 nm³.

8. The white light illuminant of claim 1, wherein the one or more phosphors emit at wavelengths between 465 nm and 650 nm.

9. The white light illuminant of claim 1, wherein the one or more phosphors can be translated in space.

10. The white light illuminant of claim 9, wherein the translation of the one or more phosphors changes the chromaticity of the white light.

11. The white light illuminant of claim 9, wherein the one or more phosphors are comprised of different colors and produce varying correlated color temperature when translated relative to the short wavelength laser light.

12. The white light illuminant of claim 1, wherein the one or more phosphors each have an emitter area of less than 0.01 cm².

13. The white light illuminant of claim 1, further comprising a movable lens.

14. The white light illuminant of claim 1, wherein the correlated color temperature of the white light is between 2000 and 8000K.

15. The white light illuminant of claim 1, wherein the color rendering index of the white light is greater than 75.

16. The white light illuminant of claim 1, wherein the luminous efficacy of the white light is greater than 325 Im/W.

17. The white light illuminant of claim 1, further comprising at least one additional light source that adds to the spectral power density of the unconverted laser light and the phosphor-converted light.

18. The white light illuminant of claim 17, wherein the at least one additional light source comprises a light-emitting diode or a laser diode.
